(19) United States
(12) Patent Application Publication
(10) Pub. No.: US 2007/0155110 A1
(43) Pub. Date: Jul. 5, 2007

(54) METHOD FOR MANUFACTURING SEMICONDUCTOR DEVICE

(76) Inventor: Dae Kyeun Kim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/613,058

(22) Filed: Dec. 19, 2006

(30) Foreign Application Priority Data
Dec. 29, 2005 (KR) 10-2005-0134726

(51) Int. Cl. H01L 21/336

(52) U.S. Cl. 438/305

(57) ABSTRACT

Embodiments relate to a method for manufacturing a semiconductor device that may improve a formation of a drain and a source of a transistor. According to embodiments, a method for manufacturing a semiconductor device may include forming a gate electrode on a semiconductor substrate, forming a first spacer at a sidewall of the gate electrode as a first insulating layer, implanting low density ions in the semiconductor substrate on which the first spacer is formed to form drain and source regions, forming a second insulating layer at an entire surface of the semiconductor substrate on which the gate electrode is formed, etching the second insulating layer to form a second spacer at a sidewall of the first spacer, and implanting high density ions in the entire surface of the semiconductor substrate in which the second spacer is formed.

The present application claims priority under 35 U.S.C. 119 and 35 U.S.C. 365 to Korean Patent Application No. 10-2005-0134726 (filed on Dec. 29, 2005), which is hereby incorporated by reference in its entirety.

### BACKGROUND OF THE INVENTION

As semiconductor devices become more highly integrated, semiconductor transistors may continuously become smaller in size. However, a continuous reduction of a size of transistors may cause a short channel effect.

To reduce or prevent the short channel effect, a thickness of a gate insulating layer may be reduced. Further, a channel between source/drain, a maximum width of depletion under a gate, may be reduced. Impurity ions in a semiconductor substrate may also be reduced.

It may also be important to form a shallow junction to reduce or prevent the short channel effect.

There have continuously been attempts to form a shallow junction by a subsequent thermal treatment process using ion implanting equipment in a manufacturing process of a semiconductor device.

A related art method for manufacturing a semiconductor device will be described with reference to the accompanying drawings.

FIGS. 1A through 1E are example cross-sectional diagrams illustrating a related art method for manufacturing a semiconductor device.

Referring to FIG. 1A, semiconductor substrate 21 may be defined by an active region and a device isolation region. Device isolation layer 22 may be formed at a device isolation region of semiconductor substrate 21, for example by an LOCOS or STI process.

Semiconductor substrate 21 may be thermally oxidized, for example at a high temperature, which may form oxide layer 23 on semiconductor substrate 21.

A polysilicon layer may be deposited at the oxide layer. The polysilicon layer and oxide layer 23 may be selectively etched to form gate electrode 24.

Referring to FIG. 1B, oxide layer 25 may be formed over a surface of semiconductor substrate 21, including gate electrode

A low density of impurity ions may be implanted in a surface of semiconductor substrate 21 using gate electrode 24 as a mask, and may thereby form Lightly Doped Drain (LDD) region 26 in a surface of semiconductor substrate 21. LDD may be formed at both sides of gate electrode 24.

LDD region 26 may be formed to overlap with a lower portion of gate electrode 24 by diffusion.

Referring to FIG. 1C, oxide layer 25 may be removed. First and second insulating layers 27 and 28, which may have different etching selectivity, maybe sequentially formed over a surface of semiconductor substrate 21, including gate electrode 24.

First insulating layer 27 may be formed as an oxide layer, and second insulating layer 28 may be formed as a nitride layer.

In this process, a quality of gate oxide layer 23 may be deteriorated or reduced due to a removal of oxide layer 25. Moreover, removal of oxide layer 25 may increase a divot depth of device isolation layer 22 which may impact a device performance.

Referring to FIG. 1D, an etch back process may be performed on surfaces of the first and second insulating layers 27 and 28, and may form first and second insulating layer sidewalls 27a and 28a at both sides of gate electrode 24.

Referring to FIG. 1E, using gate electrode 24 and the first and second insulating layer sidewalls 27a and 28a as a mask, a high density of impurity ions may be implanted in a surface of the substrate 21. Source/drain impurity region 29, that may be connected to LDD region 26, may be formed in a surface of semiconductor substrate 21.

Although subsequent process are not illustrated in the drawings, they may be general processes, for example to form an inter layer dielectric and a metal wiring.

The related art method for manufacturing a semiconductor device as described herein may have various disadvantages. For example, because the LDD region may overlap with a lower portion of the gate oxide layer, it may be susceptible to Gate Induced Drain Leakage (GIDL). This may negatively affect a performance of the semiconductor device and may cause parasitic capacitance.

### SUMMARY OF THE INVENTION

Embodiments relate to a transistor of a semiconductor device and a method for manufacturing the same. Embodiments relate to a method for manufacturing a semiconductor device. Embodiments relate to a method for manufacturing a semiconductor device that may improve a formation method of a drain and a source of a transistor.

Embodiments relate to a method for manufacturing a semiconductor device that may improve a performance of a device and may prevent an LDD region from overlapping with a lower portion of a gate electrode.

In embodiments, a method for manufacturing a semiconductor device may include forming a gate electrode on a semiconductor substrate, forming a first spacer at a sidewall of the gate electrode as a first insulating layer, implanting low density ions in the semiconductor substrate on which the first spacer may be formed to form drain and source regions, forming a second insulating layer at an entire surface of the semiconductor substrate on which the gate electrode may be formed, etching the second insulating layer to form a second spacer at a sidewall of the first spacer, and implanting high density ions in the entire surface of the semiconductor substrate in which the second spacer may be formed.

In embodiments, a method for manufacturing a semiconductor device may include forming a gate electrode on a semiconductor substrate, forming a first insulating layer at an entire surface of the semiconductor substrate on which the gate electrode may be formed, etching the first insulating layer to form a first spacer at a sidewall of the gate electrode, etching the semiconductor substrate exposed by the etching of the first insulating layer to a predetermined depth, implanting low density ions in the semiconductor substrate to form drain and source regions, forming a second insulating layer at an entire surface of the semiconductor substrate on which the gate electrode may be formed, etching the second insulating layer to form a second spacer at a sidewall of the first spacer, and implanting high density ions in the entire surface of the semiconductor substrate in which the second spacer may be formed.

In embodiments, the first insulating layer may be an oxide layer.

In embodiments, the second spacer may be formed by an etch back process after an oxide layer and a nitride layer have been sequentially deposited.

In embodiments, the high density ions may be implanted in a partial region of the drain and source regions in which the low density ions are implanted.

In embodiments, the high density ions may be implanted in source and drain regions of a low density, which may be formed at an outer side of the second spacer.

### BRIEF DESCRIPTION OF THE DRAWINGS

FIGS. 1A through 1E are example cross-sectional diagrams illustrating a related art method for manufacturing a semiconductor device; and

FIGS. 2A through 2G are example cross-sectional diagrams of a semiconductor device illustrating a method for manufacturing a semiconductor device according to embodiments.

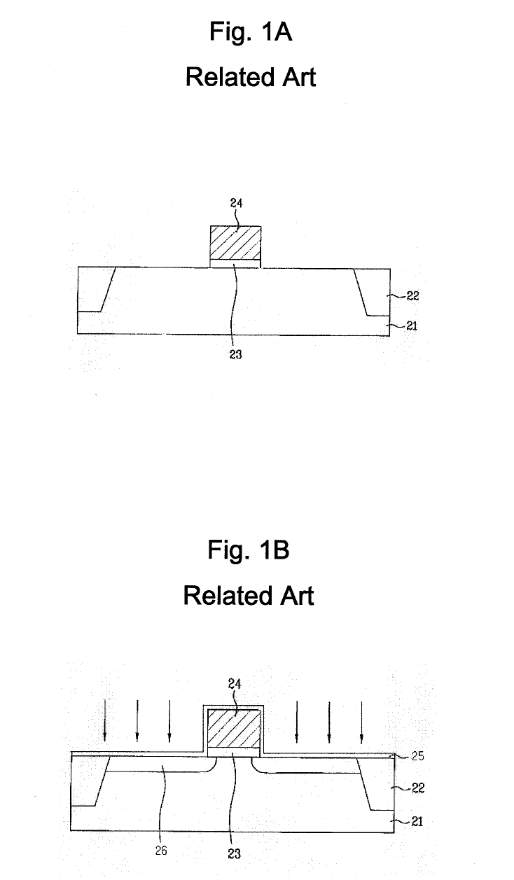

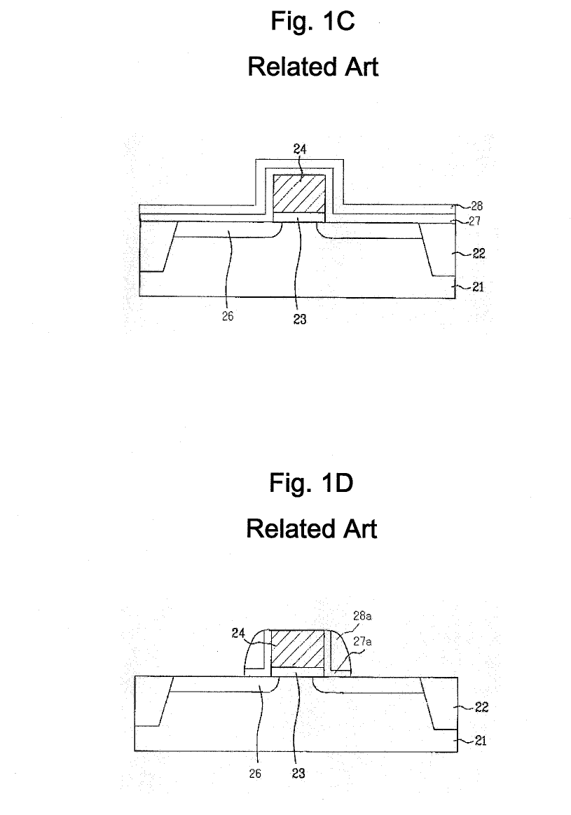

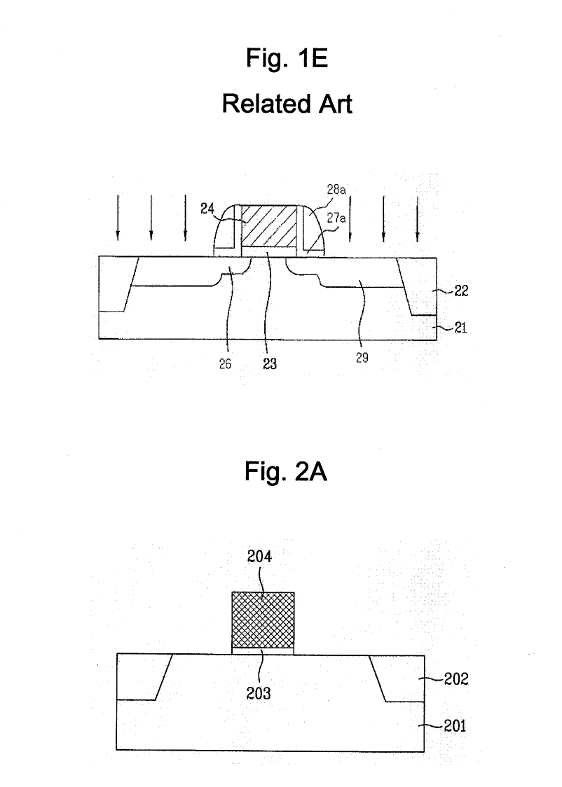

### DETAILED DESCRIPTION OF PREFERRED EMBODIMENTS

A method for manufacturing a semiconductor device according to embodiments will be described with reference to the accompanying drawings.

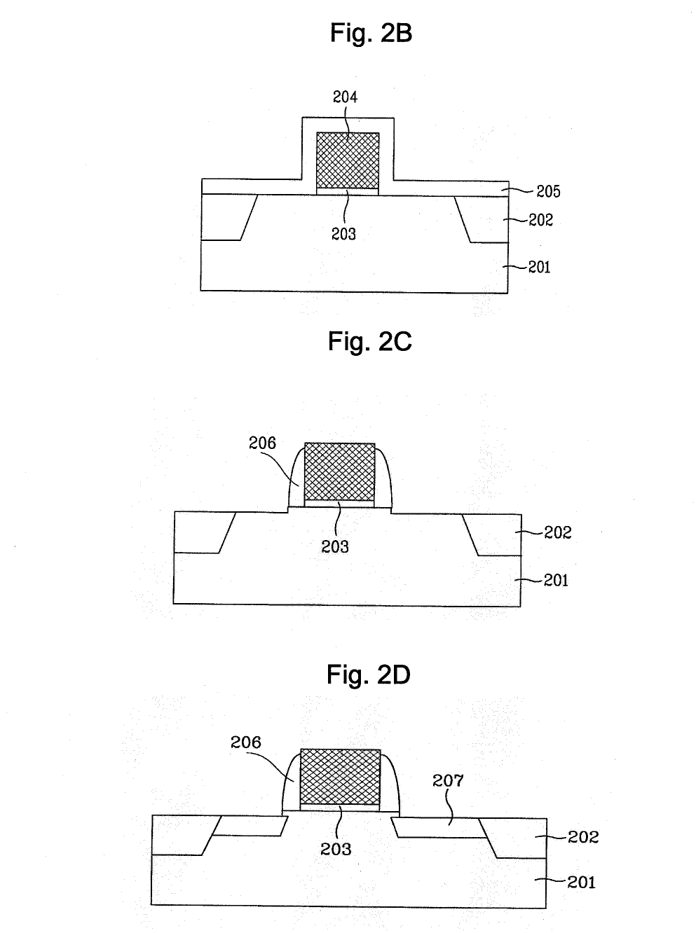

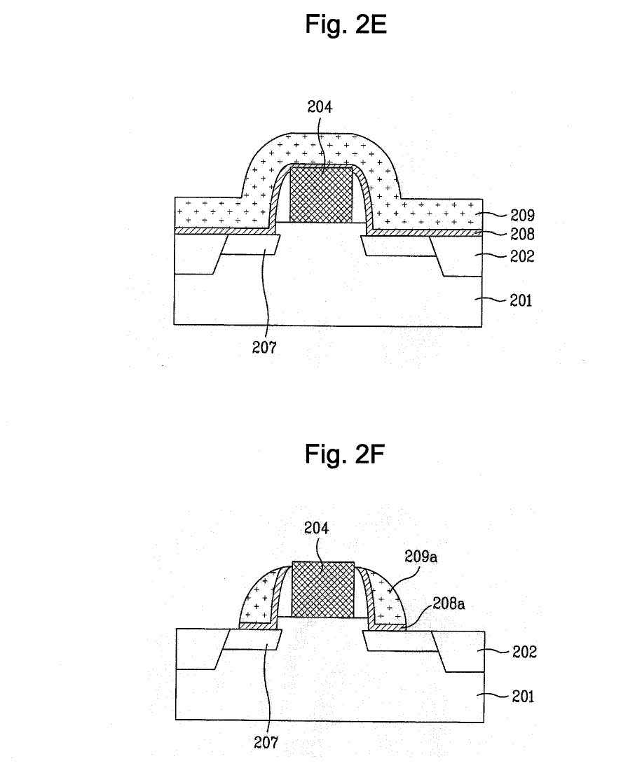

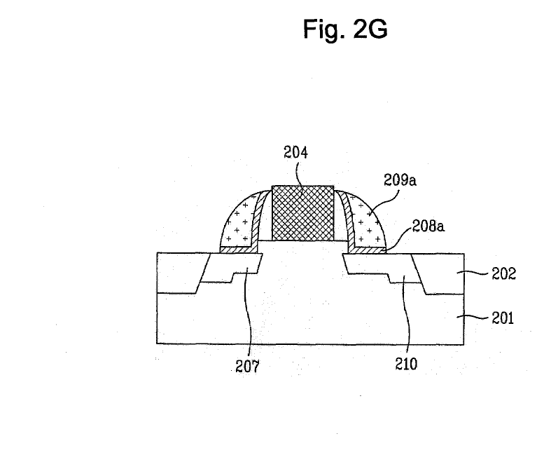

Referring to FIG. 2A, semiconductor substrate 201 may include an active region and a device isolation region. Device isolation layer 202 may be formed at a device isolation region of semiconductor substrate 201, for example by an LOCOS or STI process.

An oxide layer may be formed on semiconductor substrate 201. In embodiments, the oxide layer may be formed by deposition or a thermal oxidation process.

A polysilicon layer may be formed on the oxide layer.

The polysilicon layer and the oxide layer may be selectively etched through photolithography and etching processes, and may thereby form gate electrode 204 and gate oxide layer 203.

Referring to FIG. 2B, oxide layer 205 may be deposited on a surface of semiconductor substrate 201, including the gate electrode 204.

According to embodiments, deposited oxide layer 205 may have a thickness ranging from approximately 50 to 500 Å According to embodiments, an exact thickness may be changed and applied according to the properties of a device.

Referring to FIG. 2C, a gate spacer 206 may be formed, for example using a blanket etch.

Through the blanket etch, oxide layer 205 on semiconductor substrate 201 may be etched and semiconductor substrate 201 and oxide layer 205 may be etched to a prescribed depth.

In embodiments, an etched thickness of semiconductor substrate 201 may range from approximately 50 to 300 Å. In embodiments, the etched range of semiconductor substrate 201 may be changed according to a size of a manufactured transistor.

Referring to FIG. 2D, low density ions may be implanted to form LDD region 207.

During an LDD ion implantation, due to gate 204 and spacer 206 formed at a sidewall thereof, the junction overlap with a lower portion of the gate may be reduced.

Referring to FIG. 2E, first and second insulating layers 208 and 209, that may have different etching selectivity, may be are sequentially formed on a surface of semiconductor substrate 201, which may include gate electrode 204.

In embodiments, first insulating layer 208 may be formed of an oxide layer and second insulating layer 209 may be formed of a nitride layer.

Referring to FIG. 2F, an etch back process may be performed on surfaces of first and second insulating layers 208 and 208, and may form first and second insulating layer sidewalls 208a and 209a at both sides of gate electrode 204.

Referring to FIG. 2G, using gate electrode 204 and the first and second insulating layer sidewalls 208a and 209a as a mask, high density impurity ions may be implanted in a surface of semiconductor substrate 201. This may form source/drain impurity regions in a surface of semiconductor substrate 201, which may be connected to LDD region 207.

Although subsequent processes are not shown in the drawings, they may be general processes, and may form an inter layer dielectric and a metal wiring.

According to embodiments, prior to an implantation of low density LDD ions, a spacer may be formed at a sidewall of a gate.

Further, upon forming the spacer, a semiconductor substrate disposed around a gate region may be etched to a predetermined depth.

Accordingly, according to embodiments, during an LDD ion implantation, due to a gate and a spacer 206 formed at a sidewall thereof, a junction overlap with a lower portion of the gate may be reduced.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method comprising:
forming a gate electrode over a semiconductor substrate;
forming a first spacer at a sidewall of the gate electrode as a first insulating layer;
implanting low density ions in the semiconductor substrate over which the first spacer is formed to form drain and source regions;
forming a second insulating layer over the semiconductor substrate on which the gate electrode is formed;
etching the second insulating layer to form a second spacer at a sidewall of the first spacer; and
implanting high density ions in the semiconductor substrate over which the second spacer is formed.

2. The method of claim 1, wherein the semiconductor substrate exposed after forming the gate and first insulating layer is etched to a prescribed depth prior to forming the second insulating layer.

3. The method of claim 1, wherein the first insulating layer comprises an oxide layer.

4. The method of claim 3, wherein the first insulating layer has a thickness of approximately 50 Å˜500 Å.

5. The method of claim 1, wherein the second spacer is formed by an etch back process after an oxide layer and a nitride layer have been sequentially deposited.

6. The method of claim 1, wherein the high density ions are implanted in a partial region of the drain and source regions in which the low density ions are implanted.

7. The method of claim 1, wherein the high density ions are implanted in the source and drain regions at an outer side of the second spacer.

8. A method comprising:
forming a gate electrode over a semiconductor substrate;
forming a first insulating layer over a surface of the semiconductor substrate on which the gate electrode is formed;
etching the first insulating layer to form a first spacer at a sidewall of the gate electrode;
etching the semiconductor substrate exposed by the etching of the first insulating layer to a prescribed depth;
implanting low density ions in the semiconductor substrate to form drain and source regions;
forming a second insulating layer over the surface of the semiconductor substrate on which the gate electrode is formed;
etching the second insulating layer to form a second spacer at a sidewall of the first spacer; and
implanting high density ions in the surface of the semiconductor substrate.

9. The method of claim 8, wherein the first insulating layer comprises an oxide layer.

10. The method of claim 8, wherein the second spacer is formed by an etch back process after an oxide layer and a nitride layer have been sequentially deposited.

11. The method of claim 8, wherein the high density ions are implanted in a partial region of the drain and source regions in which the low density ions are implanted.

12. The method of claim 8, wherein the high density ions are implanted in the source and drain regions using the second spacer as a mask.

13. A device, comprising:
a gate formed over a first portion of a semiconductor substrate;
insulating gate spacers formed on sides of the gate and over the first portion of the substrate; and
an insulating layer formed on sides of the insulating gate spacers and over a second portion of the semiconductor substrate, wherein the second portion of the semiconductor substrate is etched to a first depth lower that a depth of the first portion of the semiconductor substrate.

14. The device of claim 13, wherein the insulating layer comprises a first oxide layer and a second nitride layer.

15. The device of claim 13, wherein the gate and the insulating gate spacers comprise a mask for implanting low density impurity ions.

16. The device of claim 15, wherein the gate, the insulating gate spacers, and the insulating layer comprise a mask for implanting high density impurity ions.

17. The device of claim 13, wherein the insulating gate spacers comprise an oxide layer having a thickness of approximately 50 Å˜500 Å.
